(19) United States
(12) Patent Application Publication
(10) Pub. No.: US 2023/0279544 A1
(43) Pub. Date: Sep. 7, 2023

(54) ADDITIVE CHEMICAL VAPOR DEPOSITION METHODS AND SYSTEMS

(71) Applicant: TCM Research Ltd., Co Clare (IE)

(72) Inventor: Dmitri S. Terekhov, Ontario (CA)

(21) Appl. No.: 18/023,814

(22) PCT Filed: Sep. 2, 2021
(86) PCT No.: PCT/EP2021/074300

§ 371 Date: Feb. 28, 2023

Related U.S. Application Data
(60) Provisional application No. 63/074,331, filed on Sep. 3, 2020.

(51) Int. Cl. C23C 16/44; C23C 16/01; C23C 16/48; C23C 16/458; B33Y 10/00; B33Y 30/00

(52) U.S. Cl. CPC C23C 16/4418; C23C 16/01; C23C 16/483; C23C 16/458; B33Y 10/00; B33Y 30/00

(57) ABSTRACT

A system for additive chemical vapor deposition (CVD) and (CVD) methods for producing free-standing 3D metal deposits with a controlled crystal size, the method comprising a) supplying a CVD mixture containing at least one CVD precursor into a deposition chamber having a rotatable mandrel with a deposition surface or a deposition table with a deposition surface; b) generating a radiation pattern in at least two programmable radiation modules, each programmable radiation module containing an array of individually addressable radiation transmitting and/or radiation emitting elements; and c) irradiating the deposition surface with a first radiation pattern from a first radiation module and a second radiation pattern from a second radiation module, wherein the first radiation module irradiates the deposition surface in a first direction and the second radiation module irradiates the deposition surface in a second direction, and depositing a material from the CVD mixture on the deposition surface.

### CROSS-REFERENCE To RELATED APPLICATIONS

This application is the U.S. National Stage application of PCT/EP2021/074300 which was assigned an international filing date of Sep. 2, 2021 which claims the benefit of priority from U.S. Provisional Patent Application 63/074,331 filed Sep. 3, 2020, the entire disclosure of both applications is incorporated herein by reference.

### TECHNICAL FIELD

This invention relates to additive manufacturing methods by chemical vapor deposition (CVD) and systems for carrying out the methods.

### BACKGROUND

Additive manufacturing (AM) methods are used to fabricate 3D objects from a computer-aided design (CAD) model. In some methods, laser or electron beam may be used to fuse the powder surface layer (Powder Bed Fusion). These methods include Selective Laser Melting (SLS), which is also called Direct Metal Laser Sintering (DMLS) or Laser Metal Fusion (LMF). Other methods involve a direct build of layers of metals using a stream of melted metal. These methods include LMD—Laser Deposition Welding Direct Energy Deposition (DED), Direct Metal Deposition (DMD) or Laser Cladding.

US patent publication 2004/0204785 describes a method and apparatus for creating three dimensional solid forms in metals, ceramics, organics or any combination using a computer-controlled system to deposit from a stream of material. The described system is capable of writing 3D shapes to match a computer's file of a three-dimensional shape.

U.S. Pat. No. 4,863,538 describes a method and apparatus for selectively sintering a layer of powder to produce a part comprising a plurality of sintered layers. The apparatus includes a computer controlling a laser to direct the laser energy onto the powder to produce a sintered mass. After the initial layer of powder is sintered, a new layer of powder is applied, and successive layers sintered until a completed part is formed. This method works for production of parts from metal, plastic, ceramic, or polymer substance. One of the disadvantages of these methods is a net shape occurs only in one local point where the melted material is solidified or sintered on the surface. Another limitation is the necessity for a high-power energy source to melt a feed material.

Programmable radiation modules containing liquid crystal display (LCD), digital micromirror device (DMD) or digital light processing (DLP) are used in stereolithographic additive manufacturing processes. In these processes, a typical device is directing radiation in accordance with specific patterns onto a layer of polymerizable material. A laser or light beam illuminates a specific region of polymerizable material, initiating its polymerization. After all desirable regions are polymerized, a new layer of polymerizable material is introduced, and the process is repeated.

According to US patent publication 2017/0182708, a 3D object can be formed using a multi-material stereolithographic three-dimensional printing. Layers are deposited one by one by introducing different materials into a deposition chamber and curing them using digital light processing (DLP).

In some cases, liquid crystal display (LCD) can be used as a radiation transmitter. LCD pixels are used as transmitting elements to create a 3D object. For example, PCT publication WO 2015072921 which describes an additive manufacturing device and method, employs LCD as a programmable radiation module to build 3D objects using the stereolithography method. The disadvantages of these methods are that only a polymeric material can be deposited and that the net shape is built in only one direction.

U.S. Pat. Nos. 5,230,847 and 2,834,690 describe a method for forming free standing shapes using a CVD method and a master mold. The chemical vapor deposition reaction is initiated by adding a precursor such as WF6 and a reducing gas—SiH4 or hydrogen into the deposition chamber. Pure tungsten object is formed on the surface of the heated master mold. After cooling, the master mold is dissolved in acid.

In CVD methods, a metal can be also deposited by using UV radiation. For example, U.S. Pat. No. 4,451,503 describes deposition of refractory metals such as W, Mo and Cr by decomposition of metal carbonyl vapors on a surface exposed to UV radiation. This method allows depositing fine lines according to a designed pattern. Similarly, U.S. Pat. No. 5,427,824 discloses an improved CVD apparatus for depositing uniform films.

A three-dimensional nanostructure can be fabricated using a focused ion beam CVD process as described by S. Matsui (Proc. IEEE 85, 629 (1997) and O. Lehmann, F. Foulon, M. Stuke: (NATO ASI Ser. Appl. Sci. 265, 91 (1994)). Metal rods, springs and other micro and nano shapes can be formed by this method. However, the deposition process is localized by ion or light beams and is not applicable for production of macro-metal structures.

In metal CVD process, a size and shape of metal crystals depend on speed of deposition and deposition time. Typically, deposited metal crystals have an elongated grain structure with a columnar microstructure elongated in the direction of growth. Columnar structures are sometimes disadvantageous because of their potential negative effect on grain growth. The columnar structures may lead to structural, chemical, and/or electrical anisotropy and to rapid diffusion of impurities along the grain boundaries. To overcome these problems, several solutions were proposed, including adding carbon-containing gases into a deposition chamber (F. W. Hoertel, Bureau of Mines Report of Investigations, No. 6731, 1966). Also, fine-grain crystals could be obtained by mechanical means such as rubbing or brushing at regular intervals to renucleate the deposition surface. This approach has been demonstrated in deposition of tungsten (Blocher, J. M., Jr., “Chemical Vapor Deposition,” Deposition Technologies for Films and Coatings, (R. Bunshah, ed.), pp. 348-351, Noyes Publications, Park Ridge, N.J. (1982)). However, these approaches are not fully feasible in application to complex geometric structures.

The present disclosure aims at providing methods and systems which help in overcoming these and other disadvantages of conventional additive manufacturing methods and CVD technologies.

### SUMMARY

Additive CVD methods and systems of this disclosure address at least some of the disadvantages known in the art. The methods may be used for manufacturing free-standing 3D shapes, including metal and/or metal alloy objects.

In one embodiment, the present disclosure provides an additive manufacturing system which comprises a chemical vapor deposition (CVD) chamber and deposition surface support, one or more programmable radiation modules capable of directing radiation onto a specified deposition surface and initiating chemical vapor deposition at the deposition surface, and an energy source capable of generating pulsed light of at least one specified wavelength at least one specified pulse frequency, wherein each programmable radiation module comprises individually addressable radiation emitting and/or transmitting elements capable of being activated with the pulsed light from the energy source. In some preferred embodiments, the CVD chamber comprises windows through which radiation may be directed on the deposition surface.

In another embodiment, the present disclosure provides an additive manufacturing CVD method which may produce 3D metal or metal alloy parts with predetermined crystal size. Some preferred embodiments of the method can be used to deposit selectively a specified metal or metal alloy from a mixture of CVD precursors. In some embodiments, a composite object containing sequential layers of different metals and/or metal alloys may be produced.

In some embodiments, an additive chemical vapor deposition (CVD) method in this disclosure comprises:
a) supplying a CVD mixture containing at least one CVD precursor into a deposition chamber, wherein a rotatable mandrel having a deposition surface or a deposition table having a deposition surface is positioned inside the deposition chamber;
b) generating a radiation pattern in at least two programmable radiation modules, a first radiation pattern in a first programmable radiation module and a second radiation pattern in a second programmable radiation module, each programmable radiation module containing an array of individually addressable radiation transmitting and/or radiation emitting elements; and
c) irradiating the deposition surface with the first radiation pattern from the first radiation module and the second radiation pattern from the second radiation module, wherein the first radiation module irradiates the deposition surface in a first direction and the second radiation module irradiates the deposition surface in a second direction, and causing deposition of a material from the CVD mixture on the deposition surface.

In some preferred embodiments of this CVD method, the deposited material may contain a metal, metal alloy or metal compound. In some preferred embodiments, the CVD method further comprises rotating the rotatable mandrel or the deposition table. In some preferred embodiments of the CVD method, the deposited material is deposited in accordance with a computer-aided design (CAD) model. In some preferred embodiments, the deposition surface may be irradiated through radiation-transparent windows located in one or more walls of the deposition chamber. In some preferred embodiments of the CVD method, step b) comprises transmitting a pulsed radiation beam from an energy source to the first programmable radiation module and/or second programmable radiation module and activating the individually addressable radiation-emitting and/transmitting elements with the pulsed radiation beam. In some preferred embodiments of the CVD method, the first programmable radiation module and/or second programmable radiation module contains a dynamic mask and the deposition surface is irradiated through the dynamic mask. Preferably, the dynamic mask may include one or more of the following: a liquid crystal display (LCD), a digital light processing (DLP) projector and/or digital micromirror device (DMD). In some preferred embodiments of the CVD method, the deposition surface may be irradiated in step c) at a wavelength causing selective deposition of predominantly one CVD precursor from the CVD mixture comprising more than one CVD precursors. In some preferred embodiments of the CVD method, the first programmable radiation module and the second programmable radiation module may irradiate the deposition surface at the same time causing deposition of the material in more than one direction. Some preferred embodiments of the CVD method may include those in which step c) comprises irradiating the deposition surface with radiation having a predetermined pulse frequency which controls a crystal size of deposited material according to a computer-aided design (CAD) model. Some preferred embodiments of the CVD method include those in which step c) comprises irradiating the deposition surface with radiation having a predetermined wavelength to decompose predominantly and selectively one or several of CVD precursors from the CVD mixture, according to a computer-aided design (CAD) model. In further embodiments, the CVD method may include shaping a crystal structure of deposited material by starting and stopping the deposition process using a pulsed radiation beam, according to a computer-aided design (CAD) model. In some embodiments of the CVD method, the programmable radiation modules may control a composition of deposited material by changing wavelength to predominantly decompose one CVD precursor from the CVD mixture comprising several CVD precursors.

In yet another aspect, this disclosure provides an additive CVD manufacturing system, comprising: a deposition chamber and deposition surface support, one or more programmable radiation modules capable of directing radiation onto a specified deposition surface and initiating chemical vapor deposition at the deposition surface, and an energy source capable of generating pulsed light of at least one specified wavelength at least one specified pulse frequency, wherein each programmable radiation module comprises individually addressable radiation emitting and/or transmitting elements capable of being activated with the pulsed light from the energy source. In some embodiments of the additive CVD manufacturing system, the deposition surface support may include one or more of the following: rotatable mandrel and/or deposition table. In some embodiments of the additive CVD manufacturing system, at least some walls of the deposition chamber may comprise one or more radiation transparent windows. In preferred embodiments of the additive CVD manufacturing the deposition chamber is equipped with at least one gas inlet and at least one gas outlet. In some embodiments of the additive CVD manufacturing system, the array of individually addressable radiation-emitting or transmitting elements, may be configurable to irradiate individual points of the deposition support surface. In some embodiments of the additive CVD manufacturing system, the energy source may be a programmable source of radiation capable of generating impulse light with different frequencies and/or wavelengths. In some embodiments, the additive CVD manufacturing system may comprise a turning mechanism for relative rotation between the rotatable mandrel or the deposition table and/or the radiation modules.

In yet another aspect, the present disclosure provides an alternative embodiment of a CVD method which can be performed with at least one programmable radiation module, the programmable radiation module containing an array of individually addressable radiation transmitting and/or radiation emitting elements. This alternative CVD method may comprise:
a) supplying a CVD mixture containing at least one CVD precursor into a deposition chamber, wherein a rotatable mandrel having a deposition surface or a rotatable deposition table having a deposition surface is positioned inside the deposition chamber, and wherein the deposition chamber further comprises a turning mechanism for rotating the rotatable mandrel or the rotatable deposition table;
b) generating a radiation pattern in at least one programmable radiation module, the programmable radiation module containing an array of individually addressable radiation transmitting and/or radiation emitting elements;
c) rotating the rotatable mandrel or the rotatable deposition table relative to the radiation module; and
d) irradiating the deposition surface and causing multidirectional deposition of a material from the CVD mixture on the deposition surface; wherein step c) alternates directions in which the deposition surface is irradiated.

In some preferred embodiments of this alternative CVD method, the deposited material may contain a metal, metal alloy or metal compound. In some preferred embodiments of the CVD method, the deposited material is deposited in accordance with a computer-aided design (CAD) model. In some preferred embodiments, the deposition surface may be irradiated through radiation-transparent windows located in one or more walls of the deposition chamber. In some preferred embodiments of the CVD method, step b) comprises transmitting a pulsed radiation beam from an energy source to the programmable radiation module. In some preferred embodiments of the CVD method, the programmable radiation module contains a dynamic mask and the deposition surface may be irradiated through the dynamic mask. Preferably, the dynamic mask may include one or more of the following: a liquid crystal display (LCD), a digital light processing (DLP) projector and/or digital micromirror device (DMD). In some preferred embodiments of the CVD method, the deposition surface may be irradiated in step d) at a wavelength causing selective deposition of predominantly one CVD precursor from the CVD mixture comprising more than one CVD precursors. Some preferred embodiments of the CVD method may include those in which step d) comprises irradiating the deposition surface with radiation having a predetermined pulse frequency which controls a crystal size of deposited material according to a computer-aided design (CAD) model. Some preferred embodiments of the CVD method include those in which step d) comprises irradiating the deposition surface with radiation having a predetermined wavelength to decompose predominantly and selectively one or several of CVD precursors from the CVD mixture, according to a computer-aided design (CAD) model. In further embodiments, the CVD method may include shaping a crystal structure of deposited material by starting and stopping the deposition process using a pulsed radiation beam, according to a computer-aided design (CAD) model. In some embodiments of the CVD method, the programmable radiation module may control a composition of deposited material by changing wavelength to predominantly decompose one CVD precursor from the CVD mixture comprising several CVD precursors.

### BRIEF DESCRIPTION OF THE DRAWINGS

FIG. 1 is a schematic diagram of one embodiment of a system according to this disclosure.

FIG. 2 is a schematic diagram of another embodiment of a system according to this disclosure.

### DETAILED DESCRIPTION

This disclosure provides chemical vapor deposition (CVD) methods, apparatuses, and systems useful in manufacturing three-dimensional (3D) objects, including metal and/or metal alloy parts. The CVD methods of this disclosure produce deposits in which deposited crystals grow in more than one direction. The CVD methods of this disclosure are suitable for additive manufacturing in which layers are deposited one-by-one in order to grow a three-dimensional solid object in accordance with a computer-aided design (CAD) model. The present additive CVD methods may be referred to in this disclosure as “3D CVD methods” or as “3D CVD printing.”

The 3D CVD methods according to this disclosure may be used for depositing 3D shapes specified in a computer file. One of the technical advantages of the present methods, is that the 3D CVD methods of this disclosure can deposit and grow a shape in several different directions.

Other technical advantages of present 3D CVD methods include one or more of the following: 1) producing metal and/or metal alloy macro-objects, 2) preventing undesirable formation of columnar structures in the deposited metal material, 3) controlling a size of deposited crystals and producing crystals of predetermined size, and/or 4) manufacturing parts, including metal and/or metal alloy parts according to a computer-aided design (CAD) model.

In this disclosure, chemical vapor deposition includes a process in which one or more CVD precursors are reacted and/or decomposed in a chemical vapor deposition chamber in order to produce a deposit which may be deposited over a substrate in some embodiments or as a free-standing form in accordance with a computer-aided design (CAD) model. Preferred deposits manufactured according to the CVD methods of this disclosure include 3D free-standing deposits, including metal and/or metal alloy 3D parts of predetermined shape produced in accordance with a computer-aided (CAD) model.

The additive manufacturing methods of this disclosure may be performed with one or a mixture of several CVD precursors which can be decomposed on a deposition surface by exposing the deposition surface to light/radiation and thereby producing a metal, metal compound, e.g. metal oxide, and/or metal alloy deposit. Suitable CVD precursors include, but are not limited to, metal carbonyls, metal hydro-carbonyls, metal nitroso-carbonyls, metal halogen-carbonyls, metal chlorides, metal fluorides, metal alkyls or any combination thereof. Particularly preferred CVD precursors include, but are not limited to, carbonyls, hydro-carbonyls, nitroso-carbonyls and/or halogen-carbonyls of one or more of the following metals: Ni, Fe, Co, Cr, Mn, W, Mo, platinum group metals (PGMs), or any combination thereof; fluorides of one or more of the following metals: W, Mo, Re, Ta, Nb, Ir, or any combination thereof; chlorides of one or more of the following metals and silicon: V, Cr, Zr, Hf, Ta, Nb, Si and/or PGMs, or any combination thereof; and/or alkyl precursors for one or more of the following: Al, B, Zn, Si; and/or any combination of any of these CVD precursors.

A CVD deposition chamber may be referred in this disclosure as a deposition chamber.

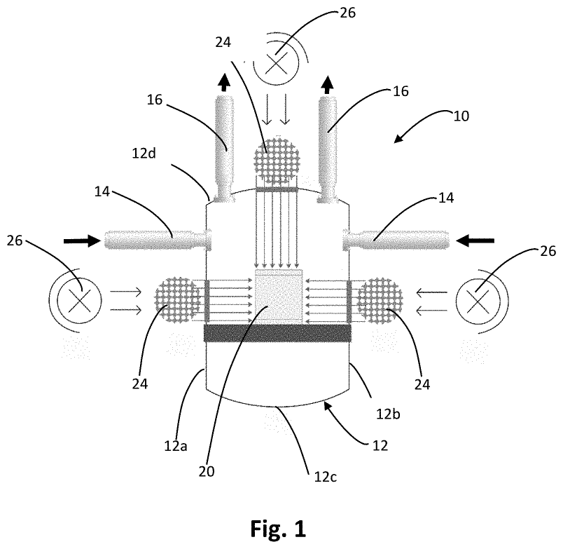

Referring to FIG. 1, this is a schematic diagram of one embodiment for a system according to this disclosure, generally 10, useful in practicing the 3D CVD methods of this disclosure. In the embodiment of FIG. 1, the system 10 comprises a CVD deposition chamber 12, one or more programmable radiation modules 24 capable of irradiating a specified surface inside the deposition chamber 12, a deposition surface support which in the embodiment of FIG. 1 may include a deposition table 18, and one or more programmable energy sources 26, wherein the energy source 26 is capable of generating pulsed light with at least one specified pulse frequency. In preferred embodiments, light may be pulsed at specified wavelength. In some preferred embodiments, the deposition chamber 12 contains one or more radiation-transparent windows 22.

In preferred embodiments, the deposition chamber 12 is a reaction chamber inside of which one or more CVD precursors may be decomposed or reacted, producing a solid deposit such as for example as a metal film deposit over a substrate, or such as a 3D free-standing object grown in accordance with a computer-aided design (CAD) model.

The deposition chamber 12 for deposition of metals and metal alloys, may be a cold wall type reaction chamber which may be water-cooled in at least some embodiments. In other embodiments, the deposition chamber 12 may be heated.

In some embodiments, the deposition chamber 12 may be made of stainless steel, ceramic, glass and/or some other material that is sufficiently inert. In some preferred embodiments, the deposition chamber 12 may contain one or more windows 22 which are transparent to light/radiation and through which a surface inside the deposition chamber 22 may be irradiated, as discussed in more detail below.

The deposition chamber 12 may be equipped with one or more means for adjusting pressure and/or temperature inside the deposition chamber 12. In some embodiments, the deposition chamber 12 may be in communication with one or more means, e.g. a pump (not shown in FIG. 1), for establishing vacuum, low atmospheric pressure, or high pressure inside the deposition chamber 12.

The deposition chamber 12 contains one or more gas inlets (14) which are used for injecting to the interior of the deposition chamber 12 a CVD precursor and/or a CVD mixture which may contain at least one CVD precursor mixed with one or more of the following: a carrier gas, a reaction catalysis, other CVD precursors and/or reducing gas. In some CVD processes, a CVD precursor or a mixture of the CVD precursors may be reacted with a reducing gas inside of the deposition chamber 12.

While in the embodiment of FIG. 1, two gas inlets 14 are shown, in other embodiments, the deposition chamber 12 may comprise only one gas inlet 14 or the deposition chamber 12 may comprise more than 2, e.g. 3, 4, or 5 gas inlets. Operation of gas inlets 14 may be controlled with valves and further controlled and coordinated by a programmable controller which may include a computer-operable pump (not shown in FIG. 1). The controller may meter an amount of CVD precursor and/or CVD mixture and/or other gases/vapors to be supplied into the deposition chamber 12. In embodiments, where a CVD precursor is to be reacted with another gas inside the deposition chamber 12, the programmable controller may also meter relative amounts of all reactants to be delivered into the deposition chamber 12.

In the embodiments with more than one gas inlets 14, all gas inlets 14 can be used to supply the same CVD precursors or CVD mixtures, or different CVD precursors can be supplied simultaneously or in sequence from different gas inlets 14. The sequential and/or simultaneous flow of different CVD precursors may be coordinated and metered by one or more controllers which may be computer-programmable. At least one of the gas inlets 14 can be also used to deliver a purge gas after the deposition has been completed.

The deposition chamber 12 may contain one or more gas outlets 16 for removing exhaust gases, unreacted CVD precursors and reaction by-products from the deposition chamber 12. It will be appreciated by a person of skill that while in the embodiment of FIG. 1, two gas outlets 16 are shown, in other embodiments the deposition chamber 12 may comprise only one gas outlet 16 or the deposition chamber 12 may comprise more than 2, e.g. 3, 4, or 5 gas outlets 16. At least some of the gas outlets 16 may be connected to a pump, e.g. a vacuum pump and gases removed from the deposition chamber 12 may be collected in a trap for detoxification (not shown in FIG. 1).

In some embodiments, a deposition table 18 is positioned in the deposition chamber 12. The deposition table 18, if present, can be fixed at one location, e.g. in a center of the deposition chamber 12, or the deposition table 18 can be movable inside the deposition chamber 12. In some embodiments, a location and movements of deposition table 18 in the deposition chamber 12 may be controlled and adjusted with a controller, e.g. a computer (not shown in FIG. 1). Operation, rotations and movements of the deposition table 18 inside the deposition chamber 12 in some embodiments may be performed with a robotic arm or by some other means (not shown in FIG. 1).

In some chemical vapor deposition methods, deposition table 18 may hold a substrate (not shown in FIG. 1). The substrate can be any type of material, including metal, glass, quartz, silicon oxide or a polymeric material. In some embodiments, a substrate is a blank or a mold or any other object onto which a desired deposit, e.g. a metal or metal alloy, is deposited during chemical vapor deposition in the deposition chamber 12.

In preferred embodiments of this disclosure, the chemical deposition method is an additive manufacturing method, a free-standing object 20 is deposited and is grown layer-by-layer from a deposition surface support which may be the deposition table 18. The shape and dimensions of the object 20 may be produced in accordance with a CAD model. These preferred embodiments may be practiced without a substrate. In some of these additive manufacturing embodiments, the deposition table 18 serves as a deposition surface support. The deposition chamber 12 may contain some additional deposition surface supports, as may be needed for producing a 3D object of specified shape.

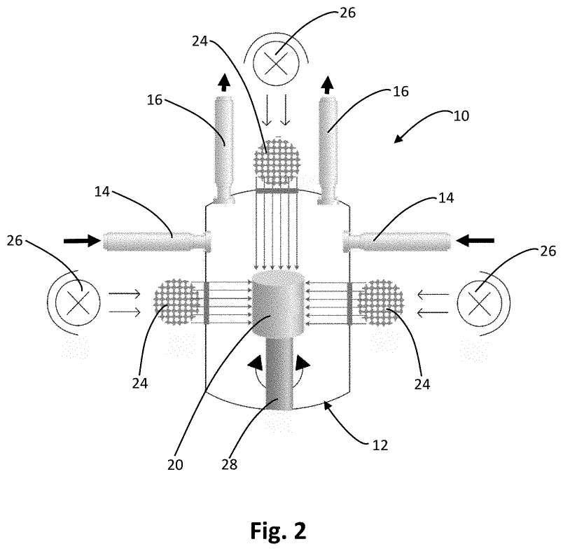

FIG. 2 shows an alternative embodiment for the system 10. In this embodiment, the deposition chamber 12 may comprise a rotatable mandrel 28 instead of the deposition table 12. All other elements in the embodiment of FIG. 2 are as described in connection with FIG. 1. At least in some of the devices and systems of the present disclosure, the mandrel 28 may have a substantially cylindrical rod around which a CVD-depositing metal/alloy or other material is shaped. Mandrels of other shapes can be also used. At least in some embodiments, the mandrel 28 is capable of rotating around its axis, shown with arrows in FIG. 2. In some embodiments, the mandrel 28 may serve as a blank or mold and it assumes a shape which can serve as a mold for producing a 3D object. In these embodiments, the mandrel 28 can be dissolved in an acid, alkali solution or by other means after the deposition has been completed.

In some preferred embodiments, the deposition chamber 12 contains several windows 22, e.g. at least 2, at least 3 or at least 4 windows 22. The deposition chamber 12 is a reaction chamber or a reaction vessel or a reaction container, and as such the deposition chamber 12 is made by walls creating an enclosure with an interior space wherein CVD reactions take place. These walls are shown as 12a, 12b, 12c and 12d in FIG. 1. In other embodiments, the deposition chamber 12 may be of a different shape, e.g. for example, hexagonal or cylindrical or spherical.

At least some windows 22 are positioned at opposite walls of the deposition chamber 12. For example, in FIG. 1 at least one window 22 is positioned in wall 12a, while a second window 22 is positioned in opposite wall 12b. The windows 22 in opposite walls 12a and 12b may be substantially aligned with each other, permitting irradiation of the same surface inside the deposition chamber 12 from each window 22.

While the rest of the deposition chamber 22 need not be transparent to radiation, the windows 22 are transparent to radiation such that a predetermined surface inside the deposition chamber 12 may be irradiated through each of the windows 22. In some alternative embodiments, the deposition chamber 22 is transparent to light/radiation and it need not have windows 22.

In preferred embodiments, the windows 22 are located in the opposite walls of the deposition chamber 12 substantially parallel to each other such that a radiation beam through each window 22 may reach the same surface, e.g. the surface of the deposition table 18. Accordingly, the deposition surface inside the deposition chamber 12 may be irradiated from different directions through the windows 22, for example, as shown with arrows in FIGS. 1 and 2. Windows 22 may be made of any material transparent to a radiation beam. For example, fused silica can be used.

The 3D CVD systems of this disclosure contain one or more programmable radiation modules 24 capable of directing radiation through windows 22 onto a selective surface inside the deposition chamber 12 and thereby initiating a CVD deposition process at that surface.

In some preferred embodiments, a CVD method of this disclosure comprises irradiating a deposition surface inside the deposition chamber 12 with one or more programmable radiation modules 24 positioned outside the deposition chamber 12 such that the programmable radiation modules 24 are capable of irradiating through the windows 22 and/or otherwise through walls of the deposition chamber 12 in embodiments wherein the deposition chamber 12 is transparent to light/radiation.

In some embodiments, at least one of the programmable radiation modules 24 may be positioned inside the deposition chamber 12 in addition to or instead of being positioned outside the deposition chamber 12. The deposition chamber 12 may further comprise a programmable turning mechanism, e.g. a robotic arm, capable of performing a relative rotation between the programmable radiation modules 24 and the deposition table 18 or mandrel 28.

In preferred embodiments, each programmable radiation module 24 comprises an array of individually addressable radiation-emitting or transmitting elements, the array being configured to irradiate individual points at the deposition surface of the growing 3D object 20, the mandrel 28 and/or the deposition table 18. The programmable radiation module 24 may comprise a dynamic mask. In preferred embodiments, the dynamic mask component may include a liquid crystal display (LCD), a digital light processing (DLP) projector and/or digital micromirror device (DMD). Using a programmable radiation module with the array of individually addressable radiation-emitting or transmitting elements improves resolution and/or speed of deposition and eliminates the need for a scanning laser.

In some preferred embodiments, the programmable radiation module 24 may comprise a liquid crystal display (LCD) containing an array of individually addressable radiation transmitting elements which are pixels of the LCD. In other embodiments, the programmable radiation module 24 may comprise a digital light processing (DLP) projector and/or digital micromirror device (DMD).

The system 10 may further comprise one or more a programmable energy source 26, capable of generating pulsed light (radiation beam) of one or more designed wavelengths, where the light may be pulsed with designed frequency. The frequency of the pulse may be short, e.g. femtoseconds. Examples of suitable radiation beams include, but are not limited to, an ultraviolet radiation beam. Suitable energy sources which can generate a pulsed radiation beam include commercially available lasers, a monochromatic light source and/or sunlight (solar radiation) which can be passed through a filter and/or a closing-and-opening shutter in order to generate a pulsed radiation beam. Any other source of electromagnetic radiation may be also suitable. Preferably, the electromagnetic source of radiation produces one or more of the following: pulsed infrared light, pulsed visible light, pulsed monochromatic light and/or pulsed ultraviolet light.

In preferred embodiments, the programmable radiation module 24 may comprise an array of individually addressable radiation-emitting and/transmitting elements. The elements are capable of being activated by the pulsed light (radiation beam) from the programmable energy source 26.

The operation of each of the programmable radiation modules 24 and the programmable energy source 26 may be controlled with a controller, which may be a computer with a processor and memory storing instructions for programs that run on the processor. Programs include a 3D deposition program with instructions which when executed on the processor generate a radiation pattern from the programmable radiation modules 24, the radiation pattern depositing a metal and/or a metal alloy with crystals of predetermined size and at specified deposition locations such that the free-standing object 20 is deposited layer-by-layer onto the deposition table 18 in accordance with a CAD model as shown in FIG. 1 or the free-standing object 20 is deposited layer-by-layer above and around the mandrel 28 as shown in FIG. 2.

In preferred embodiments, the CVD methods of these disclosure are performed by using pulse light from the one or more energy sources 26. By starting and stopping a CVD deposition process using pulse light, the present CVD methods control a size of deposited crystals. In the methods of this disclosure, a multidirectional crystal growth process may be initiated by using several energy sources 26 and/or several programmable radiation modules 24 each of which is irradiating the deposition surface from different angles and causing deposition of crystals in several directions. This multidirectional crystal growth prevents formation of a columnar structure of deposited metal which is known to be one of the disadvantages in conventional methods.

When in use, the deposition chamber 12 is supplied with and contains a CVD mixture comprising one or more CVD precursors. The CVD mixture may further comprise a carrier gas.

An energy source 26 emits a pulsed radiation beam shown with arrows in FIGS. 1 and 2. Each energy source 26 is aligned with at least one programmable radiation module 24 such that the pulsed radiation beam reaches the programmable radiation module 24 and activates individually addressable radiation-emitting and/transmitting elements in the array of the module 24. The programmable radiation module 24 produces a predetermined radiation pattern according to instructions generated based on the CAD-model. Several energy sources 26 can operate at the same wavelength and pulsing at the same frequency or they can operate sequentially and/or at different wavelength and/or at different pulse frequency.

Each programmable radiation module 24 is positioned relatively to the deposition chamber 12 and the deposition table 18 or mandrel 28 such that the radiation pattern from each programmable radiation module 24 irradiates the deposition surface of the deposition table 18 or mandrel 28. In the embodiments wherein the deposition chamber 12 contains windows 22, the irradiation may take place through the windows 22.

The irradiation of the deposition surface triggers decomposition of one or more CVD precursors from the CVD mixture and deposition of a metal, metal alloy or any other material according to a computer-aided design (CAD) module. This results in growing a free-standing object 20 layer-by-layer on the deposition table 18 or the mandrel 28.

In some embodiments, more than one, e.g. 2, 3, 4, 5, 6 or 10, programmable radiation modules 24 can be used. In these embodiments, each of the programmable radiation module 24 is positioned such that it is capable of irradiating the deposition surface in a specified direction, the specified direction of one programmable radiation module 24 being different from specified directions from other programmable radiation modules 24.

In some embodiments, the present CVD methods of this disclosure comprise irradiating the deposition surface in two or more specified directions with radiation having a predetermined pattern by using at least 2, e.g. 2, 3, 4, 5, 10 or 100, programmable radiation modules 24 simultaneously and causing simultaneous deposition of metal or metal alloy in all specified directions.

In some embodiments, the present CVD methods of this disclosure comprise irradiating the deposition surface with radiation having a predetermined pulse frequency to control crystal size of deposited material, preferably according to a computer-aided design (CAD) model.

In some embodiments, the present CVD methods of this disclosure comprise selectively irradiating the deposition surface with radiation having a predetermined wavelength to decompose predominantly one or several of CVD precursors from the CVD mixture on the deposition surface inside the deposition chamber, preferably according to a computer-aided design (CAD) model.

In some embodiments, the present CVD methods of this disclosure are performed with at least one programmable radiation module 24 comprising a dynamic mask, preferably a liquid crystal display (LCD), a digital light processing (DLP) projector and/or digital micromirror device (DMD), wherein the irradiation of the deposition surface is conducted through the dynamic mask.

In some embodiments, the present CVD methods are performed for producing a deposited material with controlled crystal structure. In these embodiments, the programmable radiation module 24 controls the crystal structure of deposited material by starting and stopping the deposition process using pulsed light.

In some embodiments, the present CVD methods may be used for depositing a selected CVD precursor from a CVD mixture of precursor. These embodiments are useful for depositing different CVD precursors sequentially in layers from the CVD mixture. These embodiments can be performed with a first CVD precursor which is predominantly decomposable at a first wavelength and a second CVD precursor which is not substantially decomposable at the first wavelength, but decomposable at a second wavelength. In these embodiments, the programmable radiation module 24 and/or programmable energy source 26 can be used to change irradiation wavelength to the first wavelength, causing predominant decomposition and deposition of the first CVD precursor and then if needed, switching to the second wavelength, thus producing a sequential deposition of different precursors from one CVD mixture.

In present CVD methods of this disclosure, the programmable radiation modules 24 cause continuous deposition of material in the deposition chamber 12, thus providing faster and more scalable production of three-dimensional structures. Accordingly, these methods are less dependent of an energy source because the programmable radiation modules 24 control a radiation pattern at which the deposition surface is irradiated. The deposition process may occur on all irradiated surfaces simultaneously, providing superior mass deposition rates compared to other CVD methods for producing metal parts.

An inherent problem in many other CVD technologies is the need to strike a balance between desired deposition speed and size of the crystals of deposited metals. A high-speed deposition process results in formation of large-size crystals. The embodiments of the present invention solve this problem and produce deposition of materials with crystal sizes controlled by pulsing light from an energy source at a predetermined frequency.

Another problem of conventional CVD processes is directional growth of crystals of deposited materials. Usually, crystals grow perpendicular to the deposition surface as large columnar grained structures, with the height of crystals being many times greater compared to their width. The use of several multiple programmable radiation modules 24 in the methods of this disclosure and simultaneous deposition of material in different directions may help with addressing this problem as well.

The CVD methods of this disclosure have an additional advantage in comparison to scanning laser systems. No scanning laser is needed for performing present methods. The rotatable mandrel or the deposition table may be the only components that are mechanically actuated, resulting in lower costs and better durability of a deposition system and apparatus.

Further, by irradiating the deposition surface with light (radiation) of different wavelengths, the described herein methods can be used to deposit materials of different compositions from the same CVD mixture, and such different materials can be deposited sequentially. This is achieved by selecting a wavelength of an energy source to decompose predominantly one of the CVD precursors in the CVD mixture. Accordingly, a composite object containing layers of different metals and/or metal alloys and/or other materials may be produced by sequentially changing a wavelength at which the deposition surface is irradiated.

The present CVD methods can be practiced in manufacturing various objects, including various metal parts. These CVD methods may find many applications in different industries, including, but not limited to, aerospace, consumer products, medical devices, industrial machines and the automotive industry.

What is claimed is:

1. An additive chemical vapor deposition (CVD) method, comprising:
a) supplying a CVD mixture containing at least one CVD precursor into a deposition chamber, wherein a rotatable mandrel having a deposition surface or a deposition table having a deposition surface is positioned inside the deposition chamber;
b) generating a radiation pattern in at least two programmable radiation modules, a first radiation pattern in a first programmable radiation module and a second radiation pattern in a second programmable radiation module, each programmable radiation module containing an array of individually addressable radiation transmitting and/or radiation emitting elements; and
c) irradiating the deposition surface with the first radiation pattern from the first radiation module and the second radiation pattern from the second radiation module, wherein the first radiation module irradiates the deposition surface in a first direction and the second radiation module irradiates the deposition surface in a second direction, and causing deposition of a material from the CVD mixture on the deposition surface.

2. The method of claim 1, wherein the deposited material contains a metal, metal alloy or metal compound.

3. The method of claim 1, wherein the method further comprises rotating the rotatable mandrel or the deposition table.

4. The method of claim 1, wherein the deposited material is deposited in accordance with a computer-aided design (CAD) model.

5. The method of claim 1, wherein the deposition surface is irradiated through radiation-transparent windows located in one or more walls of the deposition chamber.

6. The method of claim 1, wherein step b) comprises transmitting a pulsed radiation beam from an energy source to the first programmable radiation module and/or second programmable radiation module and activating the individually addressable radiation-emitting and/transmitting elements with the pulsed radiation beam.

7. The method of claim 1, wherein the first programmable radiation module and/or second programmable radiation module contains a dynamic mask and the deposition surface is irradiated through the dynamic mask.

8. The method of claim 7, wherein the dynamic mask includes one or more of the following:
a liquid crystal display (LCD), a digital light processing (DLP) projector and/or digital micromirror device (DMD).

9. The method of claim 1, wherein the deposition surface irradiated in step c) at a wavelength causing selective deposition of predominantly one CVD precursor from the CVD mixture comprising more than one CVD precursors.

10. The method of claim 1, wherein the first programmable radiation module and the second programmable radiation module irradiate the deposition surface at the same time causing deposition of the material in more than one direction.

11. The method of claim 1, wherein step c) comprises irradiating the deposition surface with radiation having a predetermined pulse frequency which controls a crystal size of deposited material according to a computer-aided design (CAD) model.

12. The method of claim 1, wherein step c) comprises irradiating the deposition surface with radiation having a predetermined wavelength to decompose predominantly and selectively one or several of CVD precursors from the CVD mixture, according to a computer-aided design (CAD) model.

13. The method of claim 1, wherein the programmable radiation modules shape a crystal structure of deposited material by starting and stopping the deposition process using a pulsed radiation beam, according to a computer-aided design (CAD) model.

14. The method of claim 1, wherein the programmable radiation modules control a composition of deposited material by changing wavelength to predominantly decompose one CVD precursor from the CVD mixture comprising several CVD precursors.

15. An additive CVD manufacturing system, comprising: a deposition chamber and deposition surface support, one or more programmable radiation modules capable of directing radiation onto a specified deposition surface and initiating chemical vapor deposition at the deposition surface, and an energy source capable of generating pulsed light of at least one specified wavelength at least one specified pulse frequency, wherein each programmable radiation module comprises individually addressable radiation emitting and/or transmitting elements capable of being activated with the pulsed light from the energy source.

16. The additive CVD manufacturing system of claim 15, wherein the deposition surface support includes one or more of the following: rotatable mandrel and/or deposition table.

17. The additive CVD manufacturing system of claim 15, wherein at least some walls of the deposition chamber comprise one or more radiation transparent windows.

18. The additive CVD manufacturing system of claim 15, wherein the deposition chamber is equipped with at least one gas inlet and at least one gas outlet.

19. The additive CVD manufacturing system of claim 15, wherein the array of individually addressable radiation-emitting or transmitting elements, is configurable to irradiate individual points of the deposition support surface.

20. The additive CVD manufacturing system of claim 15, wherein the energy source is a programmable source of radiation capable of generating impulse light with different frequencies and/or wavelengths.

21. The additive CVD manufacturing system of claim 16, comprising a turning mechanism for relative rotation between the rotatable mandrel or the deposition table and/or the radiation modules.

22. An additive chemical vapor deposition (CVD) method, comprising:
a) supplying a CVD mixture containing at least one CVD precursor into a deposition chamber, wherein a rotatable mandrel having a deposition surface or a rotatable deposition table having a deposition surface is positioned inside the deposition chamber, and wherein the deposition chamber further comprises a turning mechanism for rotating the rotatable mandrel or the rotatable deposition table;
b) generating a radiation pattern in at least one programmable radiation module, the programmable radiation module containing an array of individually addressable radiation transmitting and/or radiation emitting elements;
c) rotating the rotatable mandrel or the rotatable deposition table relative to the radiation module; and
d) irradiating the deposition surface and causing multidirectional deposition of a material from the CVD mixture on the deposition surface;
wherein step c) alternates directions in which the deposition surface is irradiated.

23. The method of claim 22, wherein the deposited material contains a metal, metal alloy or metal compound.

24. The method of claim 22, wherein the deposited material is deposited in accordance with a computer-aided design (CAD) model.

25. The method of claim 22, wherein the deposition surface is irradiated through radiation-transparent windows located in one or more walls of the deposition chamber.

26. The method of claim 22, wherein step b) comprises transmitting a pulsed radiation beam from an energy source to the programmable radiation module and activating the individually addressable radiation-emitting and/or transmitting elements with the pulsed radiation beam.

27. The method of claim 22, wherein the programmable radiation module contains a dynamic mask and the deposition surface is irradiated through the dynamic mask.

28. The method of claim 27, wherein the dynamic mask includes one or more of the following: a liquid crystal display (LCD), a digital light processing (DLP) projector and/or digital micromirror device (DMD).

29. The method of claim 22, wherein the deposition surface irradiated in step d) at a wavelength causing selective deposition of predominantly one CVD precursor from the CVD mixture comprising more than one CVD precursors.

30. The method of claim 22, wherein step d) comprises irradiating the deposition surface with radiation having a predetermined pulse frequency which controls a crystal size of deposited material according to a computer-aided design (CAD) model.

31. The method of claim 22, wherein step d) comprises irradiating the deposition surface with radiation having a predetermined wavelength to decompose predominantly and selectively one or several of CVD precursors from the CVD mixture, according to a computer-aided design (CAD) model.

32. The method of claim 22, wherein the programmable radiation module shapes a crystal structure of deposited material by starting and stopping the deposition process using a pulsed radiation beam, according to a computer-aided design (CAD) model.

33. The method of claim 22, wherein the programmable radiation module controls a composition of deposited material by changing wavelength to predominantly decompose one CVD precursor from the CVD mixture comprising several CVD precursors.
